(19) United States
(12) Patent Application Publication
(10) Pub. No.: US 2015/0277622 A1
(43) Pub. Date: Oct. 1, 2015

(54) SENSING CIRCUIT STRUCTURE AND MANUFACTURING METHOD OF SAME

(71) Applicant: J TECH MATERIAL CO., LTD., Tainan City (TW)

(72) Inventors: Po-Yi HSU, Tainan City (TW); Cheng-Wei CHIU, Tainan City (TW)

(21) Appl. No.: 14/299,039

(22) Filed: Jun. 9, 2014

(30) Foreign Application Priority Data
Mar. 31, 2014 (TW) 103112034

(51) Int. Cl. G06F 3/044; H05K 3/46; H05K 3/04; G06F 1/16

(52) U.S. Cl. CPC G06F 3/044; G06F 1/16; H05K 3/4673; H05K 3/4661; H05K 3/4664; H05K 3/04; G06F 2203/04112; G06F 2203/04103

(57) ABSTRACT

A method for making a sensing circuit structure is disclosed to provide a transparent substrate, and then to form multiple plating base layers in the transparent substrate in a spaced manner, and then to form a metal conductor layer on each plating base layer using a plating technique. Thus, the thickness of the metal conductor layers can be thinner than that formed by silver paste. The invention relates also to a sensing circuit structure made by this method.

### BACKGROUND OF THE INVENTION

1. Field of the Invention

The present invention relates to sensing circuit technology for touch panel and more particularly, to a sensing circuit structure and its manufacturing method.

2. Description of the Related Art

US Patent 20120327021 discloses a capacitive touch panel and a method for manufacturing the same. This patent discloses a sensing layer manufacturing process. This manufacturing process is substantially as follows: Employ a surface treatment process to the surface of the inner surface of the recessed transparent substrate and the resin layer, thereby forming a surface treatment layer. The surface treatment process can be a chemical etching process using an alkaline aqueous solution or catalyst, a plasma surface treatment process, or an ion beam surface treatment process. Thereafter, form a metallic seed layer on the surface treatment layer. Actually, the surface treatment layer is a resin layer for the deposition of the metallic seed layer rather than an actually existed layer in the sensing layer.

Further, the formation of the surface treatment layer as described above is complicated, relatively increasing the manufacturing cost of the sensing layer.

Further, when a sensing circuit structure made through the aforesaid prior art sensing layer manufacturing process is used in a touch screen of a mobile electronic product (such as smart phone or tablet computer), the user can seen the pattern of the sensing circuit structure of the touch screen when flipping the mobile electronic product.

### SUMMARY OF THE INVENTION

The present invention has been accomplished under the circumstances in view. It is the main object of the present invention to provide a sensing circuit structure and its manufacturing method, which reduces the visibility of the metal conductor layers in the sensing circuit structure, preventing the human eye from distinguishing the sensing circuit from the outer appearance of the sensing circuit structure.

It is another object of the present invention to provide a sensing circuit structure and its manufacturing method, wherein the metal mesh formed in the sensing circuit structure is fine and thin so that the human eye cannot distinguish the pattern of the metal mesh from the outer appearance of the transparent substrate.

To achieve these and other objects of the present invention, a sensing circuit structure manufacturing method comprises the step of: providing a transparent substrate, and then the step of forming a plurality of plating base layers in the transparent substrate in a spaced manner, and at final the step of employing a plating technique to form a metal conductor layer on each plating base layer.

The invention also provides a sensing circuit structure that comprises a transparent substrate, a plurality of plating base layers and a plurality of metal conductor layers. The plating base layers are respectively connected to the transparent substrate and arranged in a spaced manner. The metal conductor layers are respectively connected to the plating base layers. Further, each metal conductor layer has a dark surface.

The invention further provides a sensing circuit structure, which comprises a transparent substrate, a plurality of plating base layers and a plurality of metal conductor layers. The plating base layers are respectively connected to the transparent substrate, and arranged in a spaced manner. Each plating base layer has a dark color. The metal conductor layers are respectively connected to the plating base layers.

Preferably, the thickness of the metal conductor layers is smaller than 0.6 μm.

Thus, selectively through three different measures, the invention reduces the visibility of the metal conductor layers of the sensing circuit structure. The first measure is way is to let the refractive index in visible light and visible light transmittance of the transparent substrate be approximately equal to the refractive index in visible light and visible light transmittance of the plating base layers. The second measure is to darken the surfaces of the metal conductor layers. The third measure is to darken the color of the plating base layers. The second and third measures are to reduce the visible light reflectivity. Further, the invention employs a plating technique to form the metal conductor layers. Thus, the thickness of the metal conductor layer can be much thinner than the conventional silver paste-based method, reducing the visibility of the metal mesh (i.e., the metal conductor layers) to the human eye.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a schematic sectional view of a sensing circuit structure in accordance with a first embodiment of the present invention.

FIG. 2 is an enlarged view of a part of the sensing circuit structure shown in FIG. 1.

FIGS. 3-8 illustrate the fabrication of a sensing circuit structure in accordance with a second embodiment of the present invention.

FIGS. 9-11 illustrate the fabrication of a sensing circuit structure in accordance with a third embodiment of the present invention.

### DETAILED DESCRIPTION OF THE INVENTION

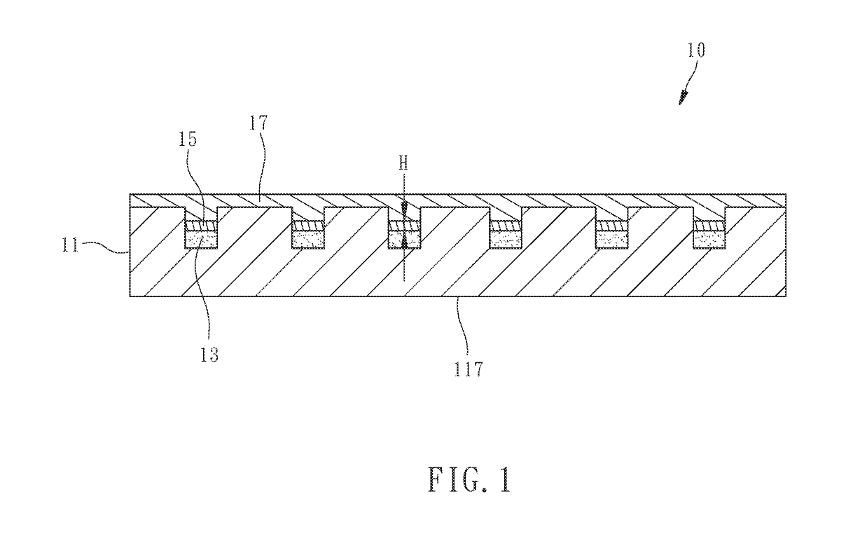

Referring to FIG. 1, a sensing circuit structure in accordance with the present invention is adapted for use in a projected capacitive touch panel, in which the human eye is difficult to observe directly the circuit pattern (metal mesh) of the sensing circuit structure when the touch panel is being flipped. The composition of the sensing circuit structure and its manufacturing method will be described hereinafter in details.

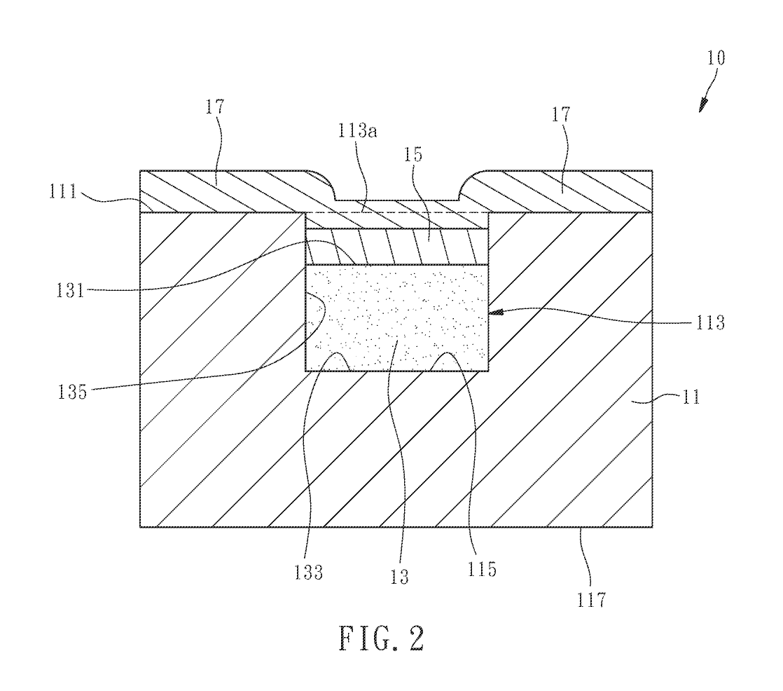

Referring to FIGS. 1 and 2, the sensing circuit structure 10 of the present invention comprises a transparent substrate 11, a plurality of plating base layers 13 and a plurality of metal conductor layers 15.

The transparent substrate 11 comprises a plurality of grooves 113 located in a surface 111 thereof. Further, the transparent substrate 11 has a first refractive index in visible light and a first visible light transmittance.

The plating base layers 13 are respectively connected to the transparent substrate 11 and respectively located in the grooves 113, wherein each plating base layer 13 has a second refractive index in visible light and a second visible light transmittance.

The metal conductor layers 15 are connected to the plating base layers 13. In this embodiment, the plating base layers 13 and the metal conductor layers 15 are respectively located in the grooves 113; further, the metal conductor layers 15 respectively face toward the entrances 113a of the respective grooves 113 (see the broken line in FIG. 2).

In other words, the metal conductor layers 15 are respectively located at the top surfaces 131 of the respective plating base layers 13; further, each plating base layer 13 has a bottom surface 133 and a circumferential surface 135 thereof connected to an inner wall surface 115 of the respective groove 113. It is to be noted that the bottom surface 133 and circumferential surface 135 of the plating base layer 13 are completely connected with the inner wall surface 115 of the groove 113 in the drawing, therefore, the assigned numbers of these components are revealed on the same line. Thus, it can be seen that the metal conductor layers 15 are disposed below the elevation of the entrance 113a of the groove 113, i.e., the metal conductor layers 15 are disposed below the elevation of the surface 111 of the transparent substrate 11.

Further, if the plating base layer 13 is also transparent, it means that the second refractive index in visible light and the first refractive index in visible light are approximately equal; the second visible light transmittance and the first visible light transmittance are approximately equal. Thus, when visible light falls upon an opposite surface 117 of the transparent substrate 11, the refractive index of the incident visible light in the transparent substrate 11 is approximately equal to that in the plating base layer 13, thus, the human eye cannot easily distinguish the sensing circuit that is formed of the metal conductor layers, reducing the visibility of the metal conductor layers 15.

In this embodiment, the metal conductor layers 15 are disposed below the elevation of the surface 111 of the transparent substrate 11, however, in actual application, the metal conductor layers 15 can be disposed above the elevation of the surface 111 of the transparent substrate 11, i.e., the plating base layers 13 can protrude over the entrances 113a of the groove 113 or located on the surface 111 of the transparent substrate 11. Thus, the metal conductor layers 15 are not limited to the design of being disposed below the elevation of the surface 111 of the transparent substrate 11, i.e., the metal conductor layers 15 and the plating base layers 13 are not limited to the design of being disposed in the grooves 113.

More particularly, the pattern of the metal conductor layers 15 is same as the pattern of the plating base layers 13, i.e., the pattern of the metal conductor layer 15 varies with the pattern of the plating base layers 13.

Referring to FIG. 1 again, the thickness H of the metal conductor layers 15 is smaller than 0.6 μm, thus, the human eye cannot easily discover the circuit pattern (metal mesh). The circuit pattern is the pattern formed by the metal conductor layers 15 in the transparent substrate 11. Preferably, the thickness H of the metal conductor layers 15 is in the range of 0.6 μm˜0.01 μm. Further, the line width of the plating base layers 13 and the metal conductor layers 15 is smaller than 10 μm, or preferably smaller than 5 μm.

The sensing circuit structure 10 of the present invention further comprises a transparent passivation layer 17. This transparent passivation layer 17 is connected to the surface 111 of the transparent substrate 11 and the metal conductor layers 15. It is to be noted that in this embodiment, the metal conductor layers 15 are disposed below the elevation of the surface 111 of the transparent substrate 11, and therefore the transparent passivation layer 17 is also connected with a part of the inner wall surface 115 of each groove 113 of the transparent substrate 11.

The above has described the composition of the sensing circuit structure 10 and a measure of the use of the principle of refraction to reduce the visibility of the metal conductor layers 15. Other two measures of the use of the principle of reflection to reduce the visibility of the metal conductor layers 15 will be described in the following sensing circuit structure manufacturing method. The manufacturing method of the sensing circuit structure in accordance with the present invention is outlined hereinafter.

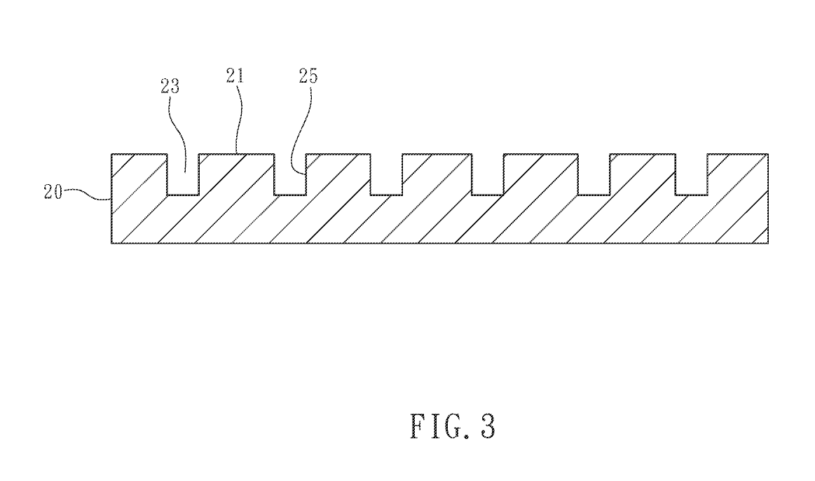

The method for making the sensing circuit structure comprises the following steps. At first, as illustrated in FIG. 3, provide a transparent substrate 20 that comprises a surface 21, and a plurality of grooves 23 located in the surface 21. The inner wall surfaces 115 of the aforesaid grooves 113 are same as the inner wall surfaces 25 in this drawing. The grooves 23 of the transparent substrate 20 can be formed by: coating a UV curable resin layer on the transparent substrate 20 (glass or acrylic plate or any other transparent film), and then using a tooling for compression molding to make the desired grooves 23 in the coated UV curable resin layer, and then curing the shaped UV curable resin layer. Because this groove-forming technique is of the known art and has been disclosed in prior art patents, it is not necessary to describe this technique further in detail.

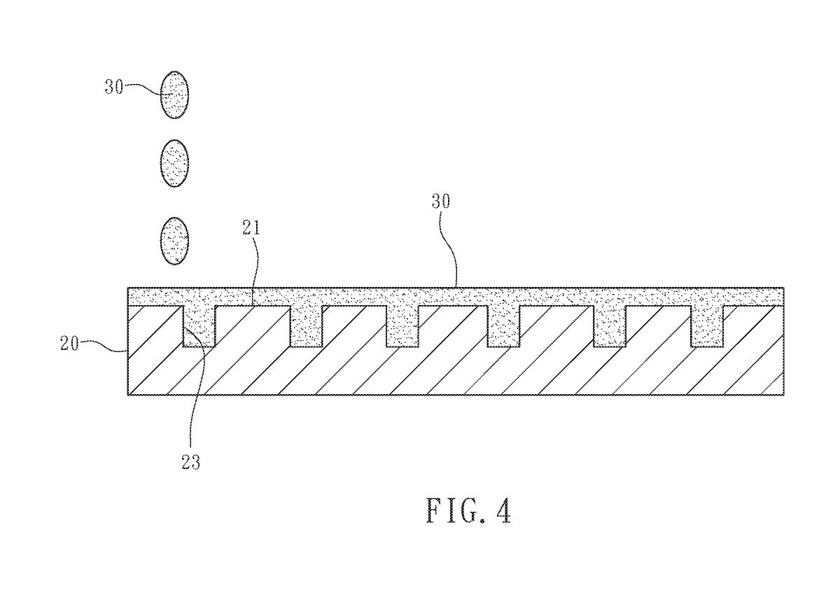

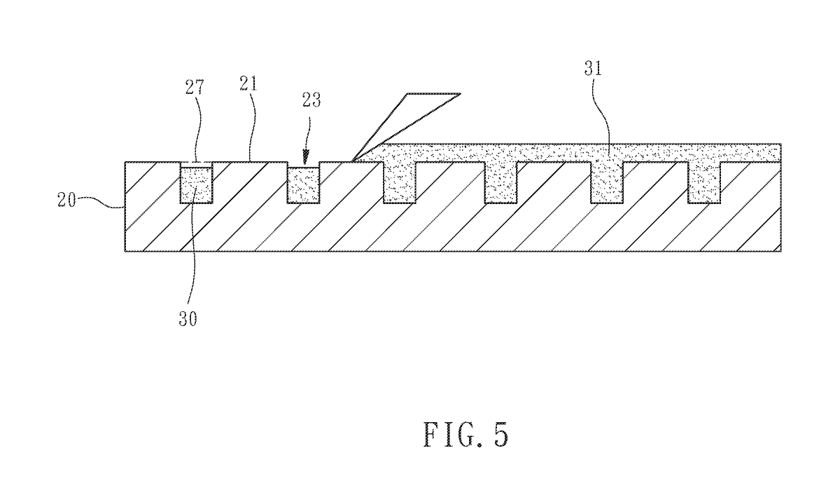

Thereafter, as illustrated in FIG. 4, thereafter, fill a plating resin 30 in the surface 21 and grooves 23 of the transparent substrate 20 to form a plating base layer 31 after the plating resin 30 is cured (see FIG. 5). In this embodiment, the plating resin 30 can be, but not limited to, acrylic acid-based photosensitive resin or conductive polymer resin. The plating base layer 31 is a metal-plated resin that can be directly formed on the transparent substrate 20 using a coating or spray-coating technique. During the coating process, the plating base layer 31 will be naturally filled in every groove 23.

In this embodiment, the plating resin 30 is a compound material. In actual practice, the plating resin 30 can be formed of two materials, i.e., one is a photosensitive resin and the other is an electroplating reactive resin. During fabrication, coating a layer of photosensitive resin and then coating a layer of electroplating reactive resin on the layer of photosensitive resin after the layer of photosensitive resin is cured. Thus, after the layer of electroplating reactive resin is cured, the plating base layer 31 will be a stacked layer structure. Therefore, the plating resin is not limited to a compound material.

Thereafter, as shown in FIG. 5, remove the plating base layer 31 from the surface 21 of the transparent substrate 20 and a part of the plating base layer 31 in each groove 23 of the transparent substrate 20, leaving the plating base layer 31 in the grooves 23 below the elevation of the entrances 27 of the grooves 23. Scraping and washing techniques can be employed to remove the plating base layer 31 from the surface 21 of the transparent substrate 20, leaving a part of the plating base layer 31 in each groove 23 of the transparent substrate 20.

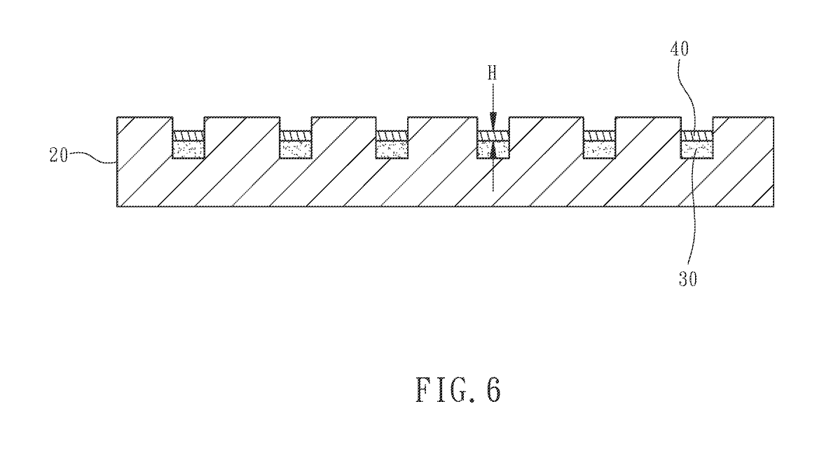

At final, as shown in FIG. 6, use a plating technique to form a metal conductor layer 40 on the plating base layer 31 in each groove of the transparent substrate 20. In this embodiment, the plating technique is preferably electroless plating.

More particularly, in this embodiment, the invention is to dip the semi-finished product (the transparent substrate 20 having the plating base layers 31 formed therein) shown in FIG. 5 in a silver nitrate solution for a predetermined period of time, and then to dip the semi-finished product in an electroless copper plating solution for another predetermined period of time, enabling a metal conductor layer 40 to be respectively formed on each respective plating base layer 31. The metal for the metal conductor layer in this embodiment is copper. Actually, if a different solution is selected, the metal for the metal conductor layer can be different, for example, silver. The thickness H of the metal conductor layers 40 thus formed is smaller than 0.6 μm. Preferably, the thickness H of the metal conductor layers 40 is in the range of 0.6 μm˜0.01 μm. In actual practice, the plating technique can be electrolytic plating but not limited to electroless plating. In the aforesaid plating process, the transparent substrate 20 and the plating base layers 31 are of different materials, the surface of the transparent substrate 20 will not be covered with any metal conductor.

It is to be noted that if the plating base layers 31 are also transparent, it means that the refractive index in visible light and visible light transmittance of the transparent substrate 20 and the refractive index in visible light and visible light transmittance of the plating base layers 31 are approximately equal, thus, the human eye cannot easily distinguish the metal conductor layers 40 from the outer appearance of the sensing circuit structure.

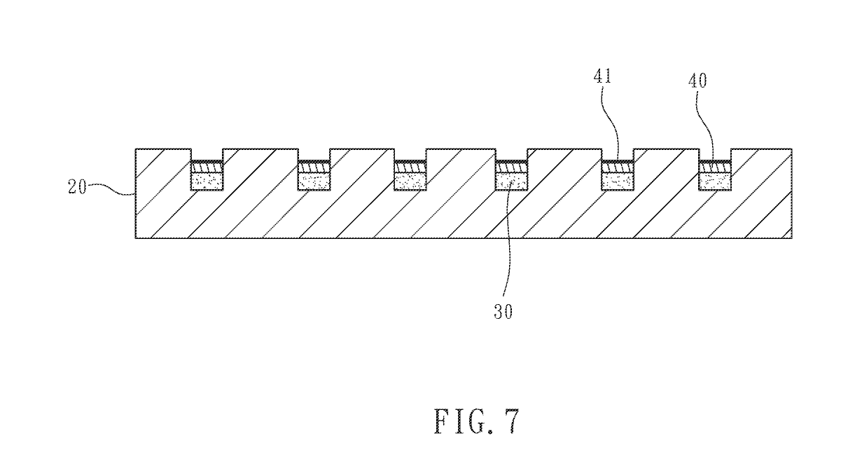

The fabrication of the sensing circuit structure in FIG. 6 has completed. Preferably, as illustrated in FIG. 7, the sensing circuit structure manufacturing method further comprises a surface treatment step to treat the surface of the metal conductor layers 40, making the color of the surfaces 41 of the metal conductor layers 40 darker to reduce its visibility. This surface treatment is to plate a dark metal, such as nickel or molybdenum on the surfaces 41 of the metal conductor layers 40 and then to blacken the plated dark metal by oxidation treatment. Thus, the blackened surfaces 41 of the metal conductor layers 40 do not reflect light, reducing visibility.

Further, in addition to the application of the method of the aforesaid surface treatment step to prevent the human eye from distinguishing the metal conductor layers 40 from the outer appearance of the transparent substrate 20, the plating resin 30 can be selected from a dark or black color resin. Because the plating resin 30 is a dark or black color resin, the plating base layer 31 is maintained in the dark or black color after cured. Thus, the dark or black plating base layer 31 does not reflect light, reducing the visibility of the metal conductor layers 40.

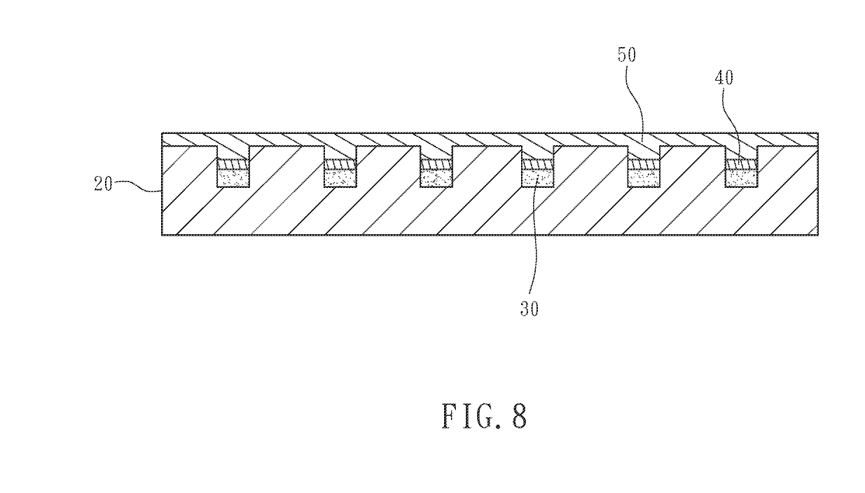

At final, as illustrated in FIG. 8, form a passivation layer 50 on the surface of the transparent substrate 20 and the metal conductor layers 40 for protection.

The step of treating the surfaces of the metal conductor layers 40 and the step of forming the passivation layer 50 on the surface of the transparent substrate 20 and the metal conductor layers 40 are preferably included in the sensing circuit structure manufacturing method. However, in actual application, these two steps can be omitted.

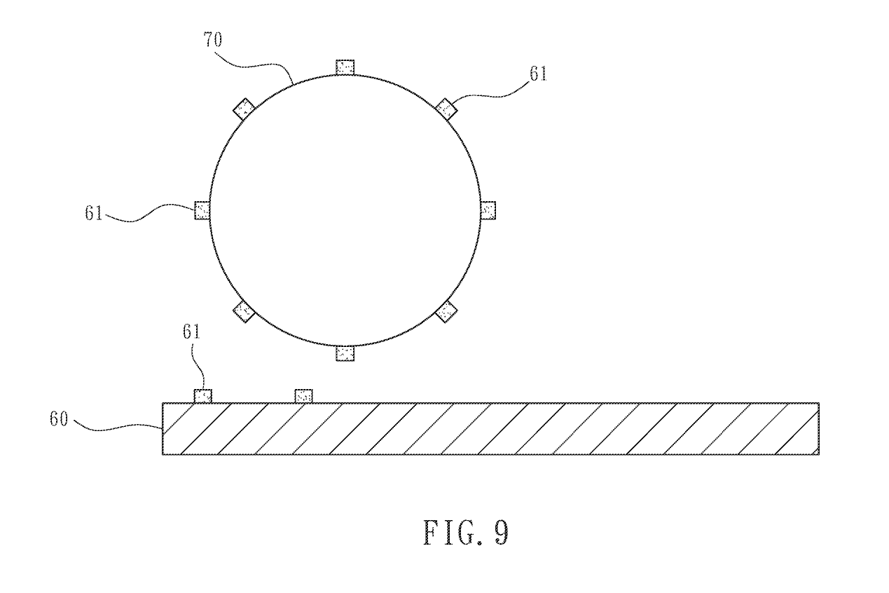

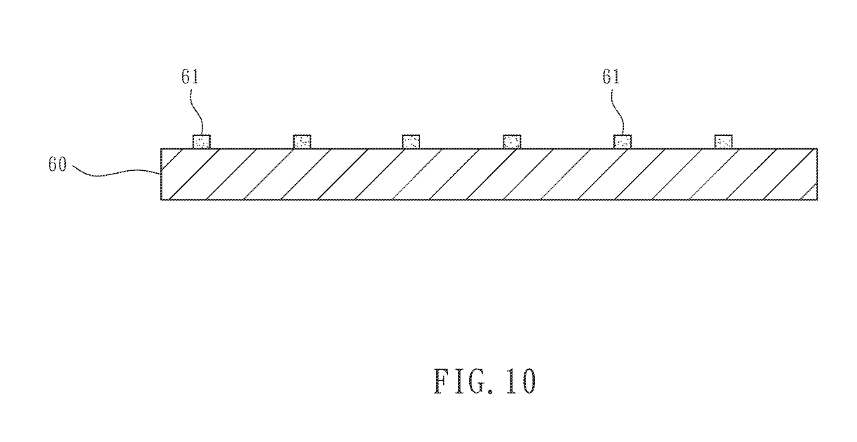

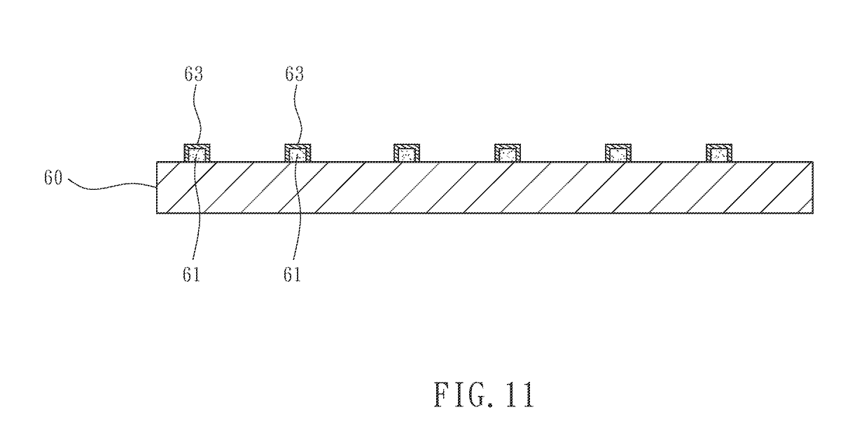

In the above-described embodiment, compression molding is employed to form the desired grooves 23 in the transparent substrate 20. However, this technique is not a limitation. In actual practice, transfer printing can be employed to make the plating base layer on the transparent substrate. As illustrated in FIG. 9, the application of transfer printing is to pre-form the plating base layers 61 on the wheel tread of a transfer printing wheel 70, and then to transfer-print the plating base layers 61 to the transparent substrate 60 one after another in a proper order during rotation of the transfer printing wheel 70. The semi-finished product thus formed, as illustrated in FIG. 10, can then be processed through follow-up processing processes. The follow-up processing processes include the step of employing a plating technique to coat a metal conductor layer 63 on the surface of each plating base layer 61 (see FIG. 11), and the step of employing a surface treatment technique to form a passivation layer on the surfaces of the metal conductor layers 63. These steps are same as that described above, and therefore, no further detailed description in this regard will be necessary. Using he transfer printing technique to form the plating base layers 61 eliminate the aforesaid plating resin coating procedure and plating base layer scraping and washing procedure, simplifying the fabrication.

From the above-described two sensing circuit structure manufacturing methods, the plating base layers and metal conductor layer of the sensing circuit structure can be disposed inside the transparent substrate, or exposed to the outside of the surface of the transparent substrate. In the aforesaid embodiments, the metal conductor layers are formed in one side of the transparent substrate (for example, X-axis circuit). In actual practice, the same manufacturing method can be employed to form the metal conductor layers (for example, Y-axis circuit) in an opposite side of the transparent substrate, or to form the metal conductor layers (i.e., X and Y axis stacked circuit) in the same side of the transparent substrate, and a X-Y axis circuit of metal conductor layers can thus be formed in the transparent substrate. Therefore, the sensing circuit structure and its manufacturing method are not limited to the aforesaid embodiments.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A sensing circuit structure manufacturing method, comprising the steps of:
providing a transparent substrate;
forming a plurality of plating base layers in said transparent substrate, said plating base layers being arranged in a spaced manner; and
employing a plating technique to form a metal conductor layer on each said plating base layer.

2. The sensing circuit structure manufacturing method as claimed in claim 1, wherein said transparent substrate comprises a plurality of grooves located in a surface thereof; and before forming said plating base layers in said transparent substrate is to fill a plating resin in the grooves of said transparent substrate and then to cure said plating resin, thereby forming said plating base layers.

3. The sensing circuit structure manufacturing method as claimed in claim 2, wherein said plating resin comprises a photosensitive resin and an electroplating reactive resin.

4. The sensing circuit structure manufacturing method as claimed in claim 2, wherein said plating resin is a dark resin.

5. The sensing circuit structure manufacturing method as claimed in claim 2, further comprising a step of removing a part of each said plating base layer in each said groove of said transparent substrate after the formation of said plating base layers in said transparent substrate, enabling said plating base layers to be disposed below an elevation of respective entrances of said grooves.

6. The sensing circuit structure manufacturing method as claimed in claim 1, wherein said plating base layers are formed in said transparent substrate using a transfer printing technique.

7. The sensing circuit structure manufacturing method as claimed in claim 1, further comprising a surface treatment step to darken a color of a surfaces of said metal conductor layers after formation of said metal conductor layers on respective said plating base layers.

8. The sensing circuit structure manufacturing method as claimed in claim 1, wherein said plating base layers are transparent, said plating base layers having a refractive index in visible light and a visible light transmittance approximately equal to the refractive index in visible light and visible light transmittance of said transparent substrate.

9. The sensing circuit structure manufacturing method as claimed in claim 1, wherein said plating technique is to dip said transparent substrate in a silver nitrate solution after the formation of said plating base layers, and then to dip said transparent substrate in an electroless copper plating solution.

10. The sensing circuit structure manufacturing method as claimed in claim 9, wherein said metal conductor layers have a thickness smaller than 0.6 μm.

11. The sensing circuit structure manufacturing method as claimed in claim 1, wherein said metal conductor layers and said plating base layers have a same pattern.

12. A sensing circuit structure, comprising:
a transparent substrate;
a plurality of plating base layers respectively connected to said transparent substrate and arranged in a spaced manner; and
a plurality of metal conductor layers respectively connected to said plating base layers, each said metal conductor layer having a dark surface.

13. The sensing circuit structure as claimed in claim 12, wherein said transparent substrate comprises a plurality of grooves located in a surface thereof; said plating base layers are connected to said transparent substrate and respectively located in said grooves.

14. The sensing circuit structure as claimed in claim 12, wherein said plating base layers have a dark color.

15. The sensing circuit structure as claimed in claim 12, wherein said metal conductor layers have a thickness a thickness smaller than 0.6 μm.

16. A sensing circuit structure, comprising:
a transparent substrate;
a plurality of plating base layers respectively connected to said transparent substrate and arranged in a spaced manner, each said plating base layer having a dark color; and
a plurality of metal conductor layers respectively connected to said plating base layers.

17. The sensing circuit structure as claimed in claim 16, wherein said transparent substrate comprises a plurality of grooves located in a surface thereof; said plating base layers are connected to said transparent substrate and respectively located in said grooves.

18. The sensing circuit structure as claimed in claim 16, wherein each said metal conductor layer has a dark surface.

19. The sensing circuit structure as claimed in claim 16, wherein said metal conductor layers have a thickness a thickness smaller than 0.6 μm.
